(19) United States
(12) Patent Application Publication
(10) Pub. No.: US 2024/0040747 A1
(43) Pub. Date: Feb. 1, 2024

(54) TWO-PHASE IMMERSION-TYPE HEAT DISSIPATION STRUCTURE HAVING SKIVED FINS

(71) Applicant: AMULAIRE THERMAL TECHNOLOGY, INC., New Taipei City (TW)

(72) Inventors: CHING-MING YANG, New Taipei City (TW); CHUN-TE WU, New Taipei City (TW); TZE-YANG YEH, New Taipei City (TW)

(21) Appl. No.: 17/875,380

(22) Filed: Jul. 27, 2022

(51) Int. Cl. H05K 7/20

(52) U.S. Cl. CPC H05K 7/203; H05K 7/20309; H05K 7/20409

(57) ABSTRACT

A two-phase immersion-type heat dissipation structure having skived fins is provided. The two-phase immersion-type heat dissipation structure includes an upper cover structure, a lower cover structure, the plurality of skived fins, and a reinforcement frame. The skived fins are integrally formed on an upper surface of the upper cover structure by a skiving process. A bottom surface of the upper cover structure has an upper sintering structure formed thereon, and an upper surface of the lower cover structure has a lower sintering structure formed thereon. A bottom surface of the lower cover structure contacts a heating element immersed in a two-phase coolant. The lower cover structure is correspondingly bonded to the upper cover structure. An inner chamber that is vacuum-sealed is formed between the bottom surface of the upper cover structure and the upper surface of the lower cover structure, and contains liquid therein.

### FIELD OF THE DISCLOSURE

The present disclosure relates to a heat dissipation structure, and more particularly to a two-phase immersion-type heat dissipation structure having skived fins.

### BACKGROUND OF THE DISCLOSURE

An immersion cooling technology is to directly immerse heat producing elements (such as servers and disk arrays) into a coolant that is non-conductive, and heat generated from operation of the heat producing elements is removed through an endothermic gasification process of the coolant. Therefore, how to dissipate heat more effectively through the immersion cooling technology has long been an issue to be addressed in the industry.

### SUMMARY OF THE DISCLOSURE

In response to the above-referenced technical inadequacy, the present disclosure provides a two-phase immersion-type heat dissipation structure having skived fins.

In one aspect, the present disclosure provides a two-phase immersion-type heat dissipation structure having skived fins. The two-phase immersion-type heat dissipation structure includes an upper cover structure, a lower cover structure, the plurality of skived fins, and a reinforcement frame. The plurality of skived fins are integrally formed on an upper surface of the upper cover structure by a skiving process. A bottom surface of the upper cover structure has an upper sintering structure formed thereon, and an upper surface of the lower cover structure has a lower sintering structure formed thereon. A bottom surface of the lower cover structure is in contact with a heating element immersed in a two-phase coolant. The lower cover structure is correspondingly bonded to the upper cover structure, such that an inner chamber that is vacuum-sealed is formed between the bottom surface of the upper cover structure and the upper surface of the lower cover structure, and the inner chamber contains liquid therein. The reinforcement frame is bonded to at least one of the upper cover structure and the lower cover structure.

In certain embodiments, at least one recess is formed on at least one of the upper cover structure and the lower cover structure.

In certain embodiments, the reinforcement frame surrounds and contacts side walls of the upper cover structure and side walls of the lower cover structure.

In certain embodiments, the reinforcement frame is bonded to the upper surface of the upper cover structure, and at least one portion of the plurality of skived fins is located in an opening formed by an inner periphery of the reinforcement frame.

In certain embodiments, the lower cover structure is correspondingly bonded to the upper cover structure by one of soldering, friction stir welding, gluing, and diffusion bonding.

In certain embodiments, the upper cover structure and the lower cover structure are each made of one of copper, copper alloy, and aluminum alloy.

In certain embodiments, the reinforcement frame is bonded to the upper cover structure and the lower cover structure by one of soldering, friction stir welding, gluing, diffusion bonding, and press-bonding.

In certain embodiments, the reinforcement frame is made of one of aluminum alloy and stainless steel.

In certain embodiments, a surface of the reinforcement frame that is bonded with the upper cover structure and the lower cover structure has a plating layer formed thereon to facilitate soldering.

In certain embodiments, the plating layer is an electroless nickel plating layer.

In certain embodiments, the reinforcement frame has two reinforcement side walls that are oppositely disposed, and each of the reinforcement side walls has at least one through hole that horizontally penetrates the reinforcement side wall.

In certain embodiments, the liquid contained in the inner chamber is water or acetone.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a top view of a two-phase immersion-type heat dissipation structure according to a first embodiment of the present disclosure;

FIG. 2 is a cross-sectional view taken along line II-II of FIG. 1;

FIG. 3 is a partial exploded view of the two-phase immersion-type heat dissipation structure according to the first embodiment of the present disclosure;

FIG. 4 is a partial exploded view of the two-phase immersion-type heat dissipation structure according to a second embodiment of the present disclosure;

FIG. 5 is a partial exploded view of the two-phase immersion-type heat dissipation structure according to a third embodiment of the present disclosure;

FIG. 6 is a cross-sectional view of the two-phase immersion-type heat dissipation structure according to a fourth embodiment of the present disclosure; and

FIG. 7 is a perspective exploded view of the two-phase immersion-type heat dissipation structure according to a fifth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

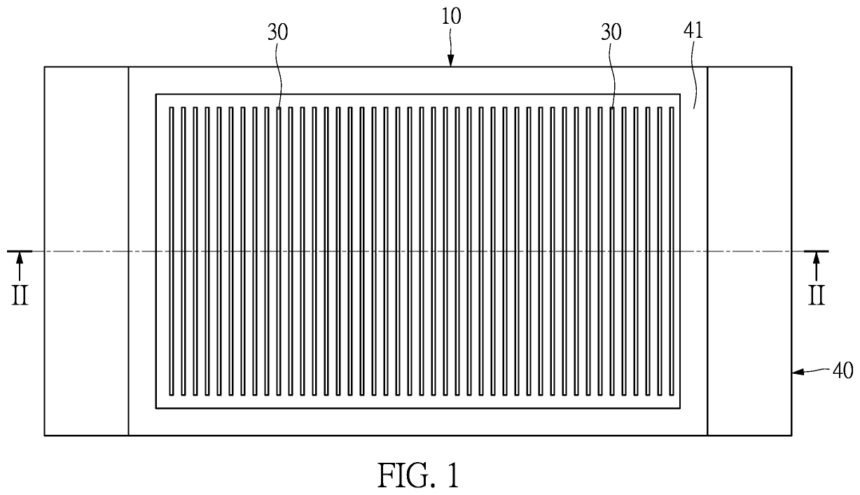

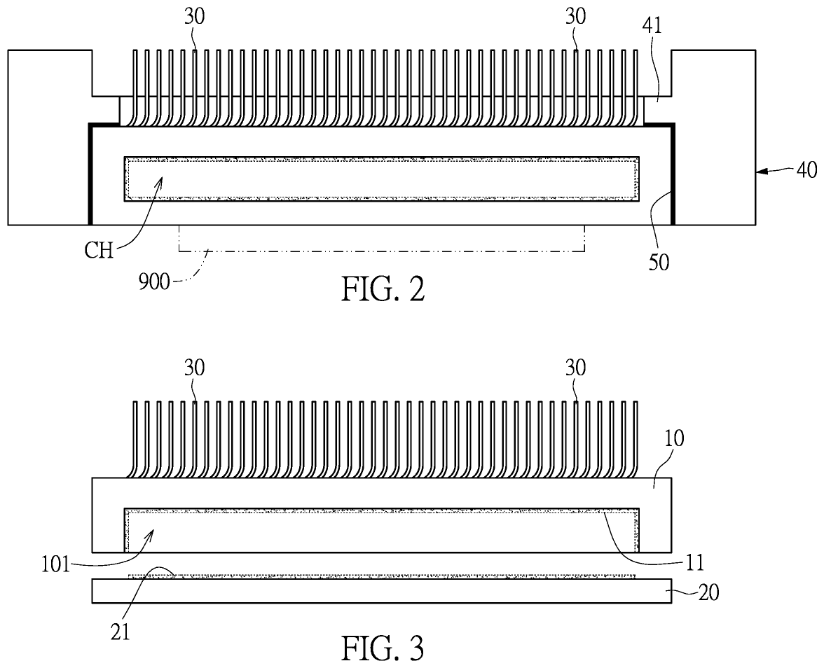

Referring to FIG. 1 to FIG. 3, one embodiment of the present disclosure provides a two-phase immersion-type heat dissipation structure having skived fins, which is used for contacting a heating element immersed in a two-phase coolant. As shown in FIG. 1 to FIG. 3, the two-phase immersion-type heat dissipation structure having skived fins provided in the present disclosure includes an upper cover structure 10, a lower cover structure 20, a plurality of skived fins 30, and a reinforcement frame 40.

In this embodiment, as shown in FIG. 3, the upper cover structure 10 is an upper cover body that has a recess 101 formed on a bottom surface thereof, and the lower cover structure 20 is a lower cover board that has a flat upper surface. The upper cover structure 10 and the lower cover structure 20 are each made of one of copper, copper alloy, and aluminum alloy. A bottom surface of the upper cover structure 10 has an upper sintering structure 11 formed thereon. That is, in this embodiment, the upper sintering structure 11 can be formed on a recessed surface of the recess 101. An upper surface of the lower cover structure 20 has a lower sintering structure 21 formed thereon. The upper sintering structure 11 and the lower sintering structure 21 can each be one of a copper powder sintering structure or a copper web sintering structure. Further, the lower cover structure 20 is correspondingly bonded to the upper cover structure 10, such that an inner chamber CH that is vacuum-sealed is formed between the bottom surface of the upper cover structure 10 and the upper surface of the lower cover structure 20. That is, inner walls of the inner chamber CH are formed by the upper sintering structure 11 at the bottom surface of the upper cover structure 10 and the lower sintering structure 21 at the upper surface of the lower cover structure 20, and the inner chamber CH contains an adequate amount of liquid therein. The liquid can be water or acetone. The lower cover structure 20 can be correspondingly bonded to the upper cover structure 10 by one of soldering, friction stir welding, gluing, and diffusion bonding.

The plurality of skived fins 30 are integrally formed on the upper surface of the upper cover structure 10 by a skiving process. That is, in this embodiment, the plurality of skived fins 30 that are very densely distributed are integrally formed on the upper surface of the upper cover structure 10 by a skiving process, so that the plurality of skived fins 30 and the upper cover structure 10 are integrally formed of a same material. Further, in this embodiment, a thickness of each of the skived fins 30 can be from 0.1 mm to 0.35 mm, the skived fins 30 can be spaced apart from each other by 0.2 mm to 0.7 mm, and a height of each of the skived fins 30 can be from 3 mm to 10 mm The bottom surface of the lower cover structure 20 can be in contact with a heating element 900 immersed in the two-phase coolant. Accordingly, for the heating element 900 immersed in the two-phase coolant, heat generated thereby can be removed through an endothermic gasification process of the two-phase coolant. In addition, the lower cover structure 20 can be in contact with the heating element 900 and absorb the heat generated thereby. In this way, the liquid in the inner chamber CH is gasified and evaporated into vapor. The vapor is dispersed to the upper cover structure 10, and the heat is rapidly conducted to the plurality of skived fins 30 that are very densely distributed and integrally formed on the upper surface of the upper cover structure 10. The heat absorbed by the skived fins 30 can then be removed through the endothermic gasification process of the two-phase coolant. After delivering the heat, the vapor in the inner chamber CH that is dispersed to the upper cover structure 10 is condensed and flows to the lower cover structure 20. By performing this loop at a high speed, the heat generated by the heating element 900 can be rapidly delivered out, thereby improving an overall immersion-type heat dissipation effect.

Further, in order to prevent issues and damages caused by warpage of the upper cover structure 10 and the lower cover structure 20, and to allow the upper cover structure 10 and the lower cover structure 20 to be more stably bonded to the heating element 900, the reinforcement frame 40 of this embodiment surrounds and contacts side walls of the upper cover structure 10 and side walls of the lower cover structure 20. In this way, an overall structural integrity can be enhanced, and the issues and damages caused by warpage can be prevented.

In this embodiment, the reinforcement frame 40 can be made of aluminum alloy or stainless steel. Further, the reinforcement frame 40 can be bonded to the upper cover structure 10 and the lower cover structure 20 by way of soldering, friction stir welding, gluing, diffusion bonding, press-bonding, and the like. Moreover, a protruding frame portion 41 is protrudingly formed on an inner periphery of the reinforcement frame 40, and abuts against the upper surface of the upper cover structure 10, so that the reinforcement frame 40 is more stably bonded to the upper cover structure 10. Further, a surface of the reinforcement frame 40 that is bonded with the upper cover structure 10 and the lower cover structure 20 has a plating layer 50 formed thereon to facilitate soldering, and the plating layer 50 is preferably an electroless nickel plating layer.

### Second Embodiment

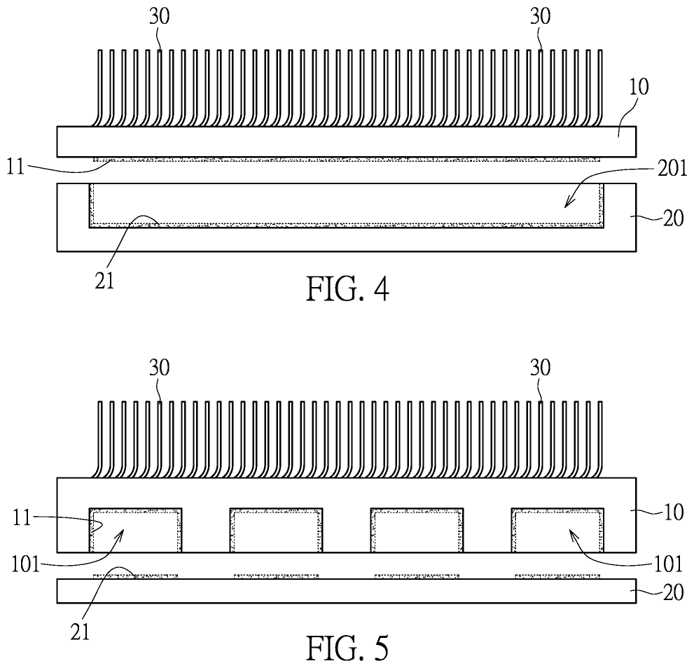

Referring to FIG. 4, a second embodiment of the present disclosure is substantially the same as the first embodiment, and the difference therebetween is described as follows.

In this embodiment, the upper cover structure 10 is an upper cover board that has a flat bottom surface, and the lower cover structure 20 is a lower cover body that has a recess 201 formed on an upper surface thereof. An upper sintering structure 11 is formed on the bottom surface of the upper cover structure 10, and the upper sintering structure 11 can have a flat shape and be uniformly distributed on the bottom surface of the upper cover structure 10. A lower sintering structure 21 is formed on the upper surface of the lower cover structure 20. That is, in this embodiment, the lower sintering structure 21 can be formed on a recessed surface of the recess 201, so that the lower sintering structure 12 can have a concave shape and be uniformly distributed on the recessed surface of the recess 201.

### Third Embodiment

Referring to FIG. 5, a third embodiment of the present disclosure is substantially the same as the first embodiment, and the difference therebetween is described as follows.

In this embodiment, the upper cover structure 10 is an upper cover body that has a plurality of recesses 101 formed on a bottom surface thereof, and the lower cover structure 20 is a lower cover board that has a flat upper surface. An upper sintering structure 11 is formed on the bottom surface of the upper cover structure 10. That is, in this embodiment, the upper sintering structure 11 can be formed on recessed surfaces of the plurality of recesses 101, and the upper sintering structure 11 can be uniformly distributed on the recessed surfaces of the plurality of recesses 101. A lower sintering structure 21 is formed on the upper surface of the lower cover structure 20, and the lower sintering structure 21 can be distributed on the upper surface of the lower cover structure 20 by corresponding in position to the recesses 101.

It should be noted that, in other embodiments, at least one of the aforementioned recesses can be formed on the upper cover structure 10 or the lower cover structure 20, or can be formed on both of the upper cover structure 10 and the lower cover structure 20.

### Fourth Embodiment

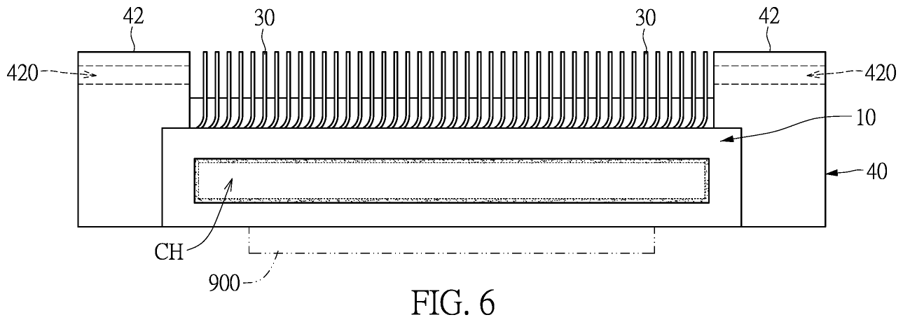

Referring to FIG. 6, a fourth embodiment of the present disclosure is substantially the same as the first embodiment, and the difference therebetween is described as follows.

In this embodiment, the reinforcement frame 40 has two reinforcement side walls 42 that are oppositely disposed. That is, the reinforcement frame 40 can have the two reinforcement side walls 42 that are higher than an upper surface of the upper cover structure 10, and a bottom surface of each of the two reinforcement side walls 42 abuts against the upper surface of the upper cover structure 10. Further, a top surface of each of the two reinforcement side walls 42 can be flush with a top surface of each of the skived fins 30, or can be higher or lower than the top surface of each of the skived fins 30. Moreover, each of the reinforcement side walls 42 has at least one through hole 420 that horizontally penetrates the reinforcement side wall, so that the two-phase coolant is allowed to flow in a lateral direction and refill an air bubble generation region. In this way, the immersion-type heat dissipation effect can be further improved.

### Fifth Embodiment

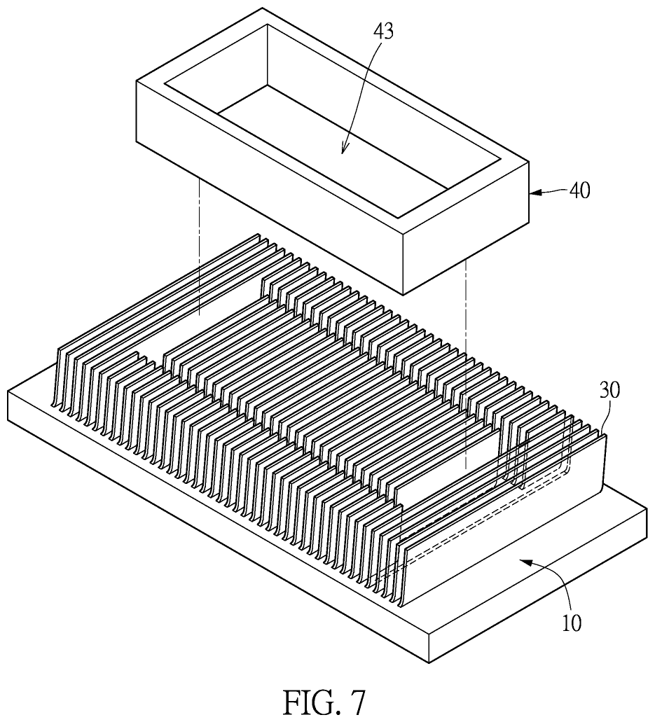

Referring to FIG. 7, a fifth embodiment of the present disclosure is substantially the same as the first embodiment, and the difference therebetween is described as follows.

In this embodiment, the reinforcement frame 40 can be a rectangular frame body, and the reinforcement frame 40 is bonded to the upper surface (a fin surface) of the upper cover structure 10. Further, at least one portion of the plurality of skived fins 30 is located in an opening 43 formed by an inner periphery of the reinforcement frame 40. Moreover, another portion of the plurality of skived fins 30 can surround an outer periphery of the reinforcement frame 40.

### Beneficial Effects of the Embodiments

In conclusion, in the two-phase immersion-type heat dissipation structure having skived fins provided by the present disclosure, by virtue of “the plurality of skived fins being integrally formed on an upper surface of the upper cover structure by a skiving process,” “a bottom surface of the upper cover structure having an upper sintering structure formed thereon, and an upper surface of the lower cover structure having a lower sintering structure formed thereon,” “a bottom surface of the lower cover structure being in contact with a heating element immersed in a two-phase coolant,” “the lower cover structure being correspondingly bonded to the upper cover structure, such that an inner chamber that is vacuum-sealed is formed between the bottom surface of the upper cover structure and the upper surface of the lower cover structure, and the inner chamber containing liquid therein,” and “the reinforcement frame being bonded to at least one of the upper cover structure and the lower cover structure,” the overall immersion-type heat dissipation effect and the overall structural integrity can be effectively improved.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A two-phase immersion-type heat dissipation structure, comprising an upper cover structure, a lower cover structure, a plurality of skived fins, and a reinforcement frame, wherein the plurality of skived fins are integrally formed on an upper surface of the upper cover structure by a skiving process; wherein a bottom surface of the upper cover structure has an upper sintering structure formed thereon, and an upper surface of the lower cover structure has a lower sintering structure formed thereon; wherein a bottom surface of the lower cover structure is in contact with a heating element immersed in a two-phase coolant; wherein the lower cover structure is correspondingly bonded to the upper cover structure, such that an inner chamber that is vacuum-sealed is formed between the bottom surface of the upper cover structure and the upper surface of the lower cover structure, and the inner chamber contains liquid therein; wherein the reinforcement frame is bonded to at least one of the upper cover structure and the lower cover structure.

2. The two-phase immersion-type heat dissipation structure according to claim 1, wherein at least one recess is formed on at least one of the upper cover structure and the lower cover structure.

3. The two-phase immersion-type heat dissipation structure according to claim 1, wherein the reinforcement frame surrounds and contacts side walls of the upper cover structure and side walls of the lower cover structure.

4. The two-phase immersion-type heat dissipation structure according to claim 1, wherein the reinforcement frame is bonded to the upper surface of the upper cover structure, and at least one portion of the plurality of skived fins is located in an opening formed by an inner periphery of the reinforcement frame.

5. The two-phase immersion-type heat dissipation structure according to claim 1, wherein the lower cover structure is correspondingly bonded to the upper cover structure by one of soldering, friction stir welding, gluing, and diffusion bonding.

6. The two-phase immersion-type heat dissipation structure according to claim 1, wherein the upper cover structure and the lower cover structure are each made of one of copper, copper alloy, and aluminum alloy.

7. The two-phase immersion-type heat dissipation structure according to claim 1, wherein the reinforcement frame is bonded to the upper cover structure and the lower cover structure by one of soldering, friction stir welding, gluing, diffusion bonding, and press-bonding.

8. The two-phase immersion-type heat dissipation structure according to claim 1, wherein the reinforcement frame is made of one of aluminum alloy and stainless steel.

9. The two-phase immersion-type heat dissipation structure according to claim 1, wherein a surface of the reinforcement frame that is bonded with the upper cover structure and the lower cover structure has a plating layer formed thereon to facilitate soldering, and the plating layer is an electroless nickel plating layer.

10. The two-phase immersion-type heat dissipation structure according to claim 1, wherein the reinforcement frame has two reinforcement side walls that are oppositely disposed, and each of the reinforcement side walls has at least one through hole that horizontally penetrates the reinforcement side wall.
